(19) United States
(12) Patent Application Publication
(10) Pub. No.: US 2014/0216520 A1
(43) Pub. Date: Aug. 7, 2014

(54) SOLAR CELL MODULE AND FABRICATING METHOD THEREOF

(71) Applicant: YUAN ZE UNIVERSITY, Zhongli City (TW)

(72) Inventors: Tien Lung CHIU, Zhongli City (TW); Shun Po YANG, Zhongli City (TW)

(73) Assignee: YUAN ZE UNIVERSITY, Zhongli City (TW)

(21) Appl. No.: 13/760,065

(22) Filed: Feb. 6, 2013

(51) Int. Cl. H01G 9/20; H01L 31/052; H01L 31/18; H01L 31/02

(52) U.S. Cl. CPC H01G 9/209; H01L 31/02013; H01L 31/0525; H01L 31/1876
USPC 136/246; 136/259; 438/65

(57) ABSTRACT

A solar cell module has a multiple reflection cavity formed by two parallel solar cell layers. A dye sensitized solar cell layer fills the multiple reflection cavity. The mechanism helps improve the photoelectric conversion efficiency. The fabricating method of the same is also described.

### TECHNICAL FIELD

The invention relates to a solar cell module and fabricating method thereof. In particular, the invention relates to a solar cell module embedded with a dye sensitized cell layer for improving the photoelectric conversion efficiency thereof. The fabricating method thereof is also described.

### RELATED ART

In recent years, with the rapid development in energy-saving technology and environmental consciousness, the solar cell has become one of the most popular industries.

In general, the traditional solar cell module makes use of monocrystalline silicon, polycrystalline silicon, or amorphous silicon to convert optical energy into electrical energy. One dopes in the semiconductor impurities to form P-type and N-type semiconductors for photoelectric conversion. However, because its photoelectric conversion efficiency has a close relation with sunlight irradiation area and incident angle, the conventional solar cell module cannot make use of reflected sunlight, causing the problem of the poor photoelectric conversion efficiency.

In view of this, some manufacturers propose the multiple reflection cavity. The solar cell layers are disposed in parallel or with a small angle, so that sunlight can undergo multiple reflections within the solar cell module. In this way, one can further use reflected sunlight to improve the photoelectric conversion efficiency. However, the reflection of sunlight may not be able to exhaust by all of the solar cell layers in the compact solar cell module. This results in a waste of energy. Therefore, the above-described method still cannot effectively solve the problem of poor photoelectric conversion efficiency.

In summary, the prior art has long had poor photoelectric conversion efficiency. It is thus imperative to have an improved means to solve this problem.

### SUMMARY

In view of the foregoing, the invention discloses a solar cell module and its fabricating method.

The disclosed solar cell module comprises: a first substrate, a first solar cell layer, a second substrate, a second solar cell layer, and a dye-sensitized cell layer. The first solar cell layer is disposed on the upper surface of the first substrate. The second substrate is disposed in parallel above the first substrate. The second solar cell layer is disposed on the lower surface of the second substrate. The first solar cell layer and the second solar cell layer form a multiple reflection cavity. The dye-sensitized solar cell fills the multiple reflection cavity.

The disclosed fabricating method of the solar cell module comprises the steps of: providing a first substrate having a first solar cell layer disposed thereon; providing a second substrate in parallel with the first substrate and providing a second solar cell layer on the lower surface of the second substrate, so that the first solar cell layer and the second solar cell layer form a multiple reflection cavity; and filling the multiple reflection cavity with a dye-sensitized solar cell layer.

The invention disclosed above differs from the prior art in that the invention uses two parallel solar cell layers to form a multiple reflection cavity, filled with a dye-sensitized solar cell layer in order to improve the sunlight exhaustion, leading to the increase of photoelectric conversion efficiency.

Using the technical means described above, the invention can achieve the goal of enhancing the photoelectric conversion efficiency.

### BRIEF DESCRIPTION OF THE DRAWINGS

The invention will become more fully understood from the detailed description given herein below illustration only, and thus is not limitative of the present invention, and wherein:

FIG. 1 is a cross-sectional view of the disclosed solar cell module;

FIG. 2 is a flowchart of the fabricating method of the solar cell module according to the invention;

FIG. 3 is a cross-sectional view of the first embodiment;

FIG. 4 is a cross-sectional view of the second embodiment; and

FIG. 5 is a schematic view showing the invention electrically connected to the secondary cell.

### DETAILED DESCRIPTION

The present invention will be apparent from the following detailed description, which proceeds with reference to the accompanying drawings, wherein the same references relate to the same elements.

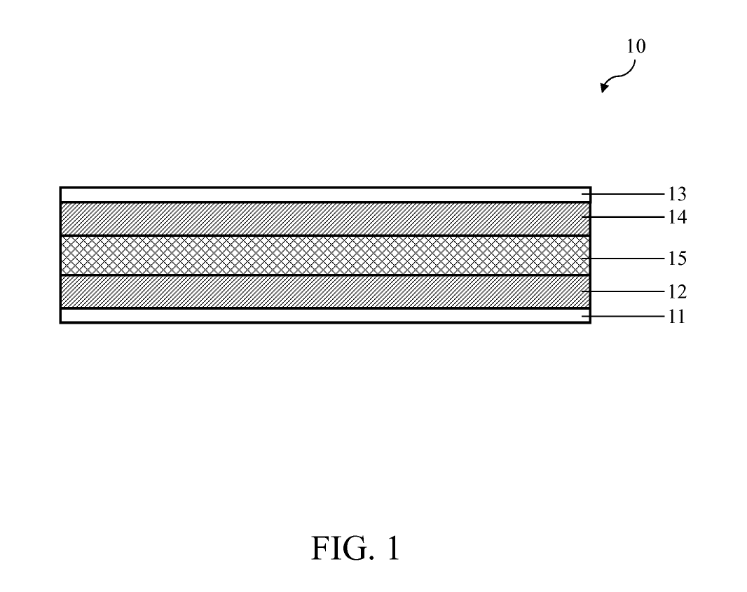

FIG. 1 is a schematic cross-sectional view of the solar cell module according to the invention. The solar cell module 10 includes: a first substrate 11, a first solar cell layer 12, a second substrate 13, a second solar cell layer 14, and a dye-sensitized solar cell layer 15. The first substrate 11 and the second substrate 13 are substrates of the solar cell. In practice, they are the flexible substrates selected from the group consisting of polyester film, plastic or ultrathin glass. It should be explained that the materials of the first substrate 11 and the second substrate 13 are not limited to the above-mentioned ones. Any material that can be used make the substrates should be included within the scope of the invention.

The first solar cell layer 12 is disposed on the upper surface of the first substrate 11. For example, using physical vapor deposition (PVD), vacuum vapor deposition, spin coating, and so on, the first substrate 11 is formed with the first solar cell layer 12 that includes a semitransparent electrode, an active layer, and an high reflective electrode. In an embodiment of the invention, the first solar cell layer 12 is an organic solar cell. However, the invention does not have any restriction on this. Any means that can be disposed on the first substrate 11 to perform photoelectric conversion should be included by the invention. In practice, the top semitransparent electrode can be made of silver (Ag) with a thickness of 12.5 nm. The active layer can be composed of poly (3-hexylthiophene) (P3HT), [6,6]-phenyl-C61 butyric acid methyl ester (PCBM). And the highly reflective bottom electrode can be made of Ag with a thickness of 100 nm. It should be noted that in practice, the top semitransparent electrode as an anode when a buffer layer of Molybdenum trioxide (MoO₃) disposed on the top semitransparent electrode, or the high reflective bottom electrode as an anode when the buffer layer of MoO₃ disposed on the high reflective bottom electrode. In other words, the anode may depend on the buffer layer of MoO₃ is disposed on the top semitransparent electrode or the high reflective bottom electrode.

The second substrate 13 is disposed in parallel above the first substrate 11. Since the second substrate 13 and the first substrate 11 are the same. It is not further described herein. In practice, one can first form the second solar cell layer 14 on the surface of the second substrate 13, and then put the side of the second solar cell layer 14 side toward the first solar cell layer 12 of the first substrate 11.

The second solar cell layer 14 is provided on the lower surface of the second substrate 13, so that the first solar cell layer 12 and the second solar cell layer 14 form a multiple reflection cavity. The multiple reflection cavity is a structure that can repeatedly reflect sunlight. Since the multiple reflection cavity belongs to the prior art, it is not further described herein. Likewise, the second solar cell layer 14 includes but is not limited to the organic solar cell.

The dye-sensitized solar cell layer 15 fills the multiple reflection cavity. In practice, the dye-sensitized solar cell layer 15 is the encapsulation layer of the first solar cell layer 12 and the second solar cell layer 14, such as a transparent conductive glass substrate, flexible organic polymer foil. It is used as the substrate of the dye-sensitized solar cell (DSSC). It is further filled with titanium dioxide (TiO2) semiconductor particles, electrolyte for promoting conductivity, as well as a dye having a sensitizing effect on sunlight, such as metal complexes of ruthenium (Ru), to form a dye-sensitized solar cell layer 15.

It should be noted that in practice, the disclosed solar cell module 10 can further contain reflectors. The reflectors are disposed on the same sides of the first substrate 11 and the second substrate 13, respectively, for guiding the sun light to the multiple reflection cavity. The configuration of the reflectors will be detailed later with reference to the accompanying figures. Moreover, the anodes and cathodes of the first solar cell layer 12, the second solar cell layer 14, and the dye-sensitized solar cell layer 15 are electrically connected to one set of wires, which are then electrically connected to the anode and cathode of a secondary cell to charge it. Likewise, the electrical connection of the solar cell module 10 and the secondary cell will be described layer with reference to the corresponding drawings.

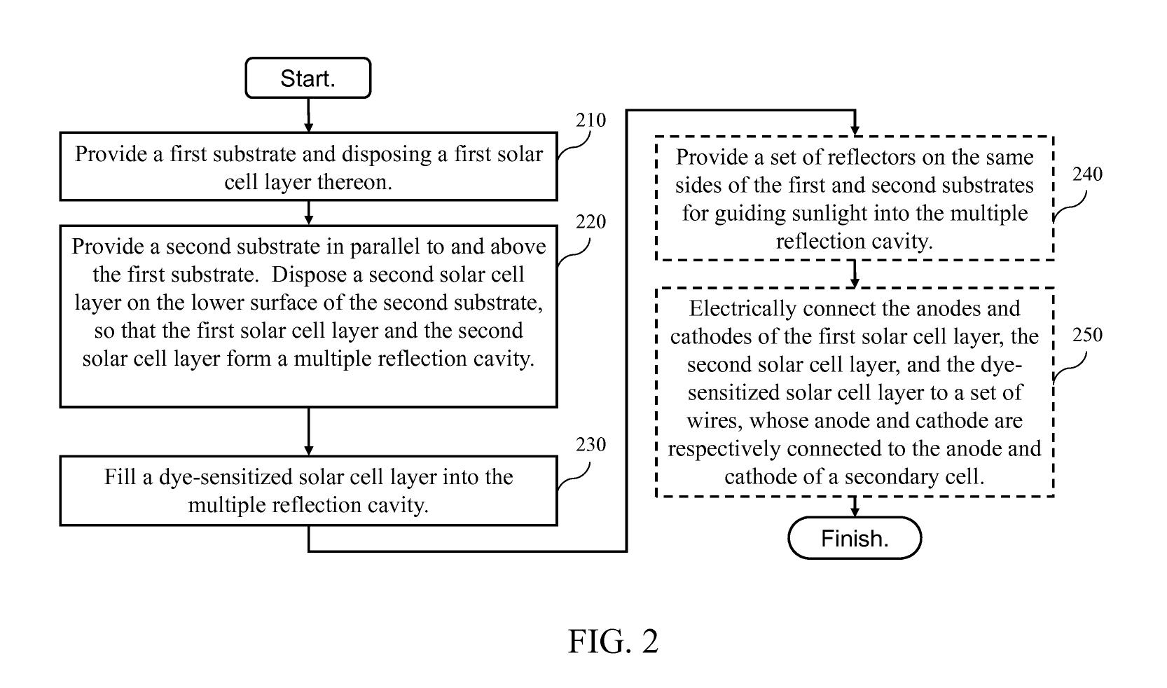

FIG. 2 is a flowchart of the fabricating method of the disclosed solar cell module. The method includes the steps of: providing a first substrate and disposing a first solar cell layer on the first substrate (step 210); providing a second substrate in parallel to and above the first substrate, and disposing a second solar cell layer on the lower surface of the second substrate, so that the first solar cell layer and the second solar cell layer form a multiple reflection cavity (step 220); and filling a dye-sensitized solar cell layer between the first solar cell layer and the second solar cell layer (step 230). Through the above steps, the two parallel solar cell layers form the multiple reflection cavity. The dye-sensitized solar cell layer fills between the two solar cell layers to enhance the photoelectric conversion efficiency.

In practice, step 230 can be followed by the steps of: disposing reflectors on the same sides of the first substrate and the second substrate, respectively, for guiding sunlight into the multiple reflection cavity (step 240); and electrically connecting the anodes and cathodes of the first solar cell layer, the second solar cell layer and the dye-sensitized solar cell layer to a set of wires, which are then electrically connected to a secondary cell (step 250).

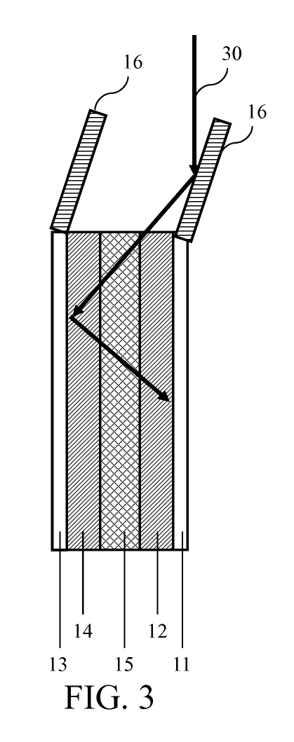

FIG. 3 is a schematic cross-sectional view of the first embodiment of the disclosed solar cell module having reflectors. As mentioned earlier, the reflectors 16 may be respectively provided on the same sides of the first substrate 11 and the second substrate 13. In practice, the reflectors 16 may adjust their angles to effectively guide the sunlight into the multiple reflection cavity, as shown by the sunlight path 30 in FIG. 3. In other words, the reflectors enables the sunlight path 30 to travel through all the solar cells, i.e., the first solar cell layer 12, the dye-sensitized solar cell layer 15, and the second solar cell layer 14.

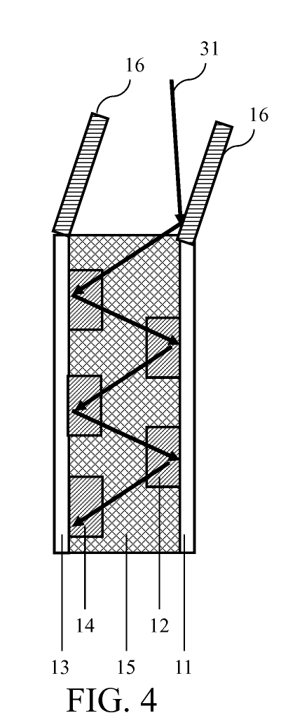

FIG. 4 is a schematic cross-sectional view of the disclosed solar cell module having reflectors according to a second embodiment. In practice, the first solar cell layer 12 and the second solar cell layer 14 can also form the multiple reflection cavity shown in FIG. 4, and the multiple reflection cavity is filled with the dye-sensitized solar cell layer 15. When the sunlight path 31 is reflected by the reflector 16, it can travel through all the solar cells. If the sunlight path 31 cannot go through all the solar cells, the photoelectric conversion can also be done by the dye-sensitized solar cell layer 15. In this case, the space in the multiple reflection cavity is fully utilized to effectively increase the photoelectric conversion efficiency.

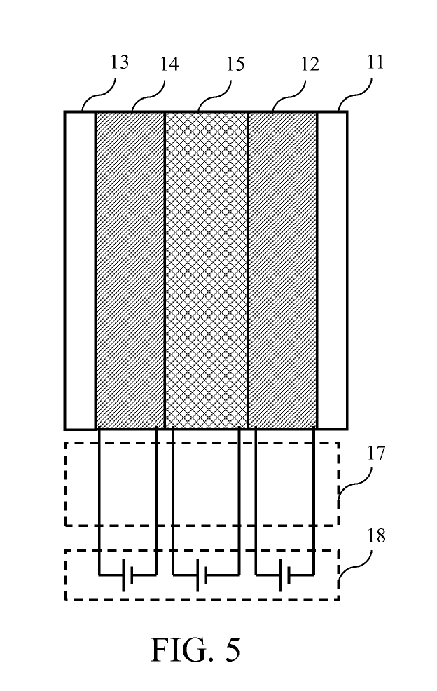

FIG. 5 is a schematic view of using the invention to electrically connect to a secondary cell. As mentioned earlier, the anodes and cathodes (not shown) of the first solar cell layer 12, the second solar cell layer 14, and the dye-sensitized solar cell layer 15 are electrically connected to one set of wires 17, whose other ends are electrically connected to the secondary cell 18. In practice, the MoO₃ disposed on a side of the second solar cell layer 14 to form an anode, the side between the second solar cell layer 14 and the second substrate 13, and the MoO₃ disposed on a side of the dye-sensitized solar cell layer 15 to form an anode, the side between the dye-sensitized solar cell layer 15 and the first solar cell layer 12. Take FIG. 5 as an example. The anode and cathode of the first solar cell layer 12 are respectively connected to the anode and cathode of the secondary cell 18 via two of this set of wires 17. The anode and cathode of the second solar cell layer 14 are respectively connected to the anode and cathode of the secondary cell 18 via another two of this set of wires 17. The anode and cathode of the dye-sensitized solar cell layer 15 are respectively connected to the anode and cathode of the secondary cell 18 via yet another two of this set of wires 17. In this way, the space of the multiple reflection cavity is fully utilized, and the dye-sensitized solar cell layer 15 can enhance the photoelectric conversion efficiency. It should particularly described that although the above-mentioned electrical connections of the anodes and the cathodes should not be used to restrict the scope of the invention. Any method that can electrically connect the anodes and cathodes of the solar cells to the anode and cathode of the secondary cell 18 is considered within the scope of the invention.

In summary, the difference between the invention and the prior art is in that two parallel solar cell layers form a multiple reflection cavity, and that the dye-sensitized solar cell layer is filled in the multiple reflection cavity. This technical means can solve the problems in the prior art, and achieves the goal of enhancing the photoelectric conversion efficiency.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A solar cell module, comprising:
a first substrate;
a first solar cell layer disposed on the upper surface of the first substrate;
a second substrate disposed in parallel to and above the first substrate;
a second solar cell layer disposed on the lower surface of the second substrate, so that the first solar cell layer and the second solar cell layer form a multiple reflection cavity; and
a dye-sensitized solar cell layer filling the multiple reflection cavity.

2. The solar cell module of claim 1 further comprising a set of reflectors disposed on the same sides of the first substrate and the second substrate, respectively, for guiding sunlight into the multiple reflection cavity.

3. The solar cell module of claim 1, wherein each of the first solar cell layer and the second solar cell layer is an organic solar cell including a semitransparent electrode, an active layer, and an high reflective electrode.

4. The solar cell module of claim 1, wherein the first substrate and the second substrate are flexible substrates whose materials are selected from the group consisting of polyester films, plastic, and ultrathin glasses.

5. The solar cell module of claim 1, wherein the anodes and cathodes of the first solar cell layer, the second solar cell layer, and the dye-sensitized solar cell layer are respectively connected to a set of wires, whose anode and cathode are then electrically connected to the anode and cathode of a secondary cell.

6. A fabricating method of a solar cell module, comprising the steps of:
providing a first substrate and disposing a first solar cell layer thereon;
providing a second substrate in parallel to and above the first substrate and disposing a second solar cell layer on the lower surface thereof, so that the first solar cell layer and the second solar cell layer form a multiple reflection cavity; and
filling a dye-sensitized solar cell layer into the multiple reflection cavity.

7. The fabricating method of claim 6 further comprising the step if providing a set of reflectors on the same sides of the first substrate and the second substrate, respectively, for guiding sunlight into the multiple reflection cavity.

8. The fabricating method of claim 6, wherein each of the first solar cell layer and the second solar cell layer is an organic solar cell including a semitransparent electrode, an active layer, and an high reflective electrode.

9. The fabricating method of claim 6, wherein the first substrate and the second substrate are flexible substrates whose materials are selected from the group consisting of polyester films, plastic, and ultrathin glasses.

10. The fabricating method of claim 6 further comprising the step of connecting the anodes and cathodes of the first solar cell layer, the second solar cell layer, and the dye-sensitized solar cell layer to a set of wires and connecting the anode and cathode of the set of wires to the anode and cathode of a secondary cell.
